(19) United States
(12) Patent Application Publication
(10) Pub. No.: US 2024/0347604 A1
(43) Pub. Date: Oct. 17, 2024

(54) GROUP III ELEMENT NITRIDE SEMICONDUCTOR SUBSTRATE, EPITAXIAL SUBSTRATE, AND FUNCTIONAL ELEMENT

(71) Applicant: NGK INSULATORS, LTD., Nagoya-shi Aichi (JP)

(72) Inventors: Kentaro NONAKA, Gifu-shi (JP); Sota MAEHARA, Nagoya-shi (JP); Yoshitaka KURAOKA, Okazaki-shi (JP); Katsuhiro IMAI, Nagoya-shi (JP)

(21) Appl. No.: 18/754,464

(22) Filed: Jun. 26, 2024

Related U.S. Application Data
(63) Continuation of application No. PCT/JP2023/001299, filed on Jan. 18, 2023.

(30) Foreign Application Priority Data
Feb. 10, 2022 (JP) 2022-019868

(51) Int. Cl. H01L 29/20; H01L 21/02; H01L 21/66; H01L 29/207

(52) U.S. Cl. CPC H01L 29/2003; H01L 21/02362; H01L 22/26; H01L 29/207

(57) ABSTRACT

A Group-III element nitride semiconductor substrate includes a first surface and a second surface. A minimum value of a specific resistance in the first surface is 1×10⁷ Ω·cm or more, and the minimum value of the specific resistance in the first surface is 0.01 or more times as large as a maximum value of the specific resistance in the first surface.

### CROSS-REFERENCE TO RELATED APPLICATIONS

This application is a continuation under 35 U.S.C. 120 of International Application PCT/JP2023/001299 having the International Filing Date of 18 Jan. 2023 and having the benefit of the earlier filing date of Japanese Application No. 2022-019868, filed on 10 Feb. 2022. Each of the identified applications is fully incorporated herein by reference.

### BACKGROUND OF THE INVENTION

### 1. Field of the Invention

The present invention relates to a Group-III element nitride semiconductor substrate. More specifically, the present invention relates to a Group-III element nitride semiconductor substrate including a main surface and a back surface in a front and back relationship, the Group-III element nitride semiconductor substrate being capable of suppressing variations in characteristics between devices formed on the substrate.

### 2. Description of the Related Art

A nitride semiconductor has been widely applied to, for example, a light-emitting device, such as an LED or an LD, and a semiconductor material for a high-frequency and high-power electronic device because the semiconductor has a wide band gap of a direct transition type, and has a high breakdown field and a high saturated electron velocity.

A high-electron mobility transistor (HEMT) structure, which is obtained by laminating and forming AlGaN serving as a “barrier layer” and GaN serving as a “channel layer” on a freestanding GaN substrate, has been known as a typical structure of a nitride electronic device. The structure takes advantage of the following feature: a high-concentration two-dimensional electron gas is produced at a laminated interface between AlGaN and GaN by large polarization effects (a spontaneous polarization effect and a piezoelectric polarization effect) peculiar to a nitride material.

The nitride electronic device is generally produced by using a base substrate made of a dissimilar material that is easily commercially available, such as sapphire, SiC, or Si. However, there is a problem in that many defects occur in a GaN film heteroepitaxially grown on such dissimilar material substrate owing to a difference in lattice constant or thermal expansion coefficient between GaN and the dissimilar material substrate.

Meanwhile, when the GaN film is homoepitaxially grown on a GaN substrate, defects resulting from the above-mentioned difference in lattice constant or thermal expansion coefficient do not occur, and hence the GaN film shows satisfactory crystallinity. Accordingly, when a nitride HEMT structure is produced on the GaN substrate, the mobility of a two-dimensional electron gas present at the laminated interface between AlGaN and GaN increases, and hence improvements in characteristics of a HEMT device (semiconductor device) produced by using the structure can be expected.

However, a GaN substrate produced by a hydride vapor phase epitaxy method (HVPE method), the substrate being commercially available, generally shows an n-conductivity type owing to oxygen impurities incorporated into its crystal. When the HEMT device is driven at a high voltage, the conductive GaN substrate serves as a leakage current path between a source electrode and a drain electrode. Accordingly, to produce the HEMT device, a semi-insulating GaN substrate is desirably adopted.

To obtain the semi-insulating GaN substrate, it is effective to dope an element for forming a deep acceptor level into a GaN crystal.

A substrate containing Fe, Mn, Zn, or the like as a doping element has been reported as a semi-insulating and freestanding GaN substrate (Patent Literatures 1 to 5). However, when HEMTs are produced on such semi-insulating and freestanding GaN substrate to provide a GaN-HEMT device, such variations in characteristics between the HEMT devices as described below may be observed: leakage currents increase in part of the HEMT devices to reduce the withstand voltages of the devices. Accordingly, a HEMT device having sufficiently high characteristics has not been provided yet.

### CITATION LIST

### Patent Literature

[PTL 1] JP 2006-24597 A

[PTL 2] JP 2012-246195 A

[PTL 3] JP 2016-000694 A

[PTL 4] JP 6705831 B2

[PTL 5] JP 6737800 B2

### SUMMARY OF THE INVENTION

An object of the present invention is to provide a Group-III element nitride semiconductor substrate including a first surface and a second surface, the Group-III element nitride semiconductor substrate being capable of suppressing variations in characteristics between devices formed on the substrate.

[1] According to at least one embodiment of the present invention, there is provided a Group-III element nitride semiconductor substrate. The Group-III element nitride semiconductor substrate includes: a first surface; and a second surface. A minimum value of a specific resistance in the first surface is 1×10⁷ Ω·cm or more, and the minimum value of the specific resistance in the first surface is 0.01 or more times as large as a maximum value of the specific resistance in the first surface.

[2] In the above-mentioned item [1], measurement of the specific resistance is continuously performed at measurement intervals of 10 mm or less.

[3] In the above-mentioned item [1] or [2], measurement of the specific resistance is performed through mapping measurement in the first surface by an electric capacitance method.

[4] In any one of the above-mentioned items [1] to [3], the Group-III element nitride semiconductor substrate includes Zn as a dopant.

[5] In any one of the above-mentioned items [1] to [4], an oxygen concentration in the Group-III element nitride semiconductor substrate measured by SIMS is from 2×10¹⁶ atoms/cm³ to 6×10¹⁶ atoms/cm³.

[6] In any one of the above-mentioned items [1] to [5], the Group-III element nitride semiconductor substrate is free of a nanopipe therein.

[7] In any one of the above-mentioned items [1] to [6], the Group-III element nitride semiconductor substrate has a diameter of 75 mm or more.

[8] According to another aspect of the present invention, there is provided an epitaxial substrate. The epitaxial substrate includes: the Group-III element nitride semiconductor substrate of any one of the above-mentioned items [1] to [7]; a buffer layer formed of at least one kind selected from AlGaN and AlN; a channel layer formed of GaN; and a barrier layer formed of at least one kind selected from InAlGaN, InAlN, and AlGaN. The buffer layer, the channel layer, and the barrier layer are arranged in the stated order on the first surface of the Group-III element nitride semiconductor substrate.

[9] According to still another aspect of the present invention, there is provided a functional device. The functional device includes: the Group-III element nitride semiconductor substrate of any one of the above-mentioned items [1] to [7]; a buffer layer formed of at least one kind selected from AlGaN and AlN; a channel layer formed of GaN; and a barrier layer formed of at least one kind selected from InAlGaN, InAIN, and AlGaN. The buffer layer, the channel layer, and the barrier layer are arranged in the stated order on the first surface of the Group-III element nitride semiconductor substrate.

According to the present invention, the Group-III element nitride semiconductor substrate including the first surface and the second surface, the Group-III element nitride semiconductor substrate being capable of suppressing variations in characteristics between the devices formed on the substrate, can be provided.

### BRIEF DESCRIPTION OF THE DRAWINGS

FIG. 1 is a typical schematic sectional view of a Group-III element nitride semiconductor substrate according to an embodiment of the present invention.

FIG. 2 is a typical schematic plan view of the Group-III element nitride semiconductor substrate according to the embodiment of the present invention when seen from a first surface side.

FIGS. 3A to 3C are schematic explanatory views for illustrating a method of producing the Group-III element nitride semiconductor substrate according to the embodiment of the present invention.

FIG. 4 is a schematic sectional view for illustrating a sectional structure of a HEMT device formed so as to include an epitaxial substrate according to an embodiment of the present invention.

FIG. 5 is a mapping chart for showing the results of the mapping measurement of the specific resistance of a wafer (C1) obtained in Comparative Example 1.

FIG. 6 is a mapping chart for showing the results of the mapping measurement of the specific resistance of a wafer (C2) obtained in Comparative Example 2.

FIG. 7 is a mapping chart for showing the results of the mapping measurement of the specific resistance of a wafer (C3) obtained in Comparative Example 3.

FIG. 8 is a mapping chart for showing the results of the mapping measurement of the specific resistance of a wafer (1) obtained in Example 1.

FIG. 9 is a mapping chart for showing the results of the mapping measurement of the specific resistance of a wafer (2) obtained in Example 2.

FIG. 10 is a mapping chart for showing the results of the mapping measurement of the specific resistance of a wafer (3) obtained in Example 3.

FIG. 11 is an observation view obtained by subjecting a region, which has shown a low resistance in the measurement of the specific resistance of the wafer (C1) obtained in Comparative Example 1, to measurement with a transmission electron microscope.

### DESCRIPTION OF THE EMBODIMENTS

When the expression “weight” is used herein, the expression may be replaced with “mass” that is commonly used as an SI unit representing a weight.

### Group-III Element Nitride Semiconductor Substrate

A Group-III element nitride semiconductor substrate according to an embodiment of the present invention is typically a freestanding substrate formed of a Group-III element nitride crystal. In this description, the term “freestanding substrate” means a substrate that is not deformed or broken by its own weight at the time of its handling, and hence can be handled as a solid. The freestanding substrate may be used as each of the substrates of various semiconductor devices, such as a light-emitting device and a power-controlling device.

The Group-III element nitride semiconductor substrate according to the embodiment of the present invention typically has a wafer shape (substantially complete round shape). However, the substrate may be processed into any other shape such as a rectangular shape as required.

Any appropriate size may be adopted as the size (diameter) of the Group-III element nitride semiconductor substrate according to the embodiment of the present invention to the extent that an effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches). The size (diameter) of the Group-III element nitride semiconductor substrate according to the embodiment of the present invention is preferably 75 mm or more. When the Group-III element nitride semiconductor substrate according to the embodiment of the present invention is such a large-diameter Group-III element nitride semiconductor substrate having a large size (diameter) as described above, the Group-III element nitride semiconductor substrate according to the embodiment of the present invention is easily applied to a high-frequency and high-power electronic device, and in particular, is easily applied to a device handling large power, the device having a large device size along with the handling.

Specific examples of the large-diameter Group-III element nitride semiconductor substrate include a 4-inch wafer, a 6-inch wafer, an 8-inch wafer, and a 12-inch wafer.

The thickness of the Group-III element nitride semiconductor substrate according to the embodiment of the present invention (when the thickness is not constant, the thickness of a site having the largest thickness) is preferably 100 μm or more, more preferably from 300 μm to 1,000 μm.

Typical examples of the Group-III element nitride include gallium nitride (GaN), aluminum nitride (AlN), indium nitride (InN), and a mixed crystal thereof. Those nitrides may be used alone or in combination thereof.

The Group-III element nitride is specifically GaN, AlN, InN, GaₓAl₁₋ₓN (1>x>0), GaₓIn₁₋ₓN (1>x>0), AlₓIn₁₋ₓN (1>x>0), or GaₓAl_{y}In_{z}N (1>x>0, 1>y>0, x+y+z=1).

The Group-III element nitride is preferably doped with any one of Fe, Mn, and Zn as a doping element because the effect exhibited by the embodiment of the present invention can be further expressed. The nitride is more preferably doped with Zn from the viewpoint that its resistance value is easily increased and the distribution of the resistance values in its surface can be further reduced. In addition, the Group-III element nitride may contain an element other than the doping component. Examples of the element include hydrogen (H), oxygen (O), and silicon (Si).

The plane direction of the Group-III element nitride semiconductor substrate may be set to any one of a c-plane, an m-plane, an a-plane, and a specific crystal plane tilted from each of the c-plane, the a-plane, and the m-plane, and particularly when the plane direction is set to the c-plane, the effect exhibited by the embodiment of the present invention can be further expressed. Examples of the specific crystal plane tilted from each of the c-plane, the a-plane, and the m-plane may include so-called semipolar planes, such as a {11-22} plane and a {20-21} plane. In addition, the plane direction is permitted to include not only a so-called just plane vertical to the c-plane, the a-plane, the m-plane, or the specific crystal plane tilted from each of the planes but also an off-angle in the range of ±5°.

The Group-III element nitride semiconductor substrate according to the embodiment of the present invention is a Group-III element nitride semiconductor substrate including a first surface and a second surface. When the first surface is defined as a main surface, and the second surface is defined as a back surface, as long as the plane direction of the Group-III element nitride semiconductor substrate is the c-plane, the main surface is typically a Group-III element polar surface, and the back surface is typically a nitrogen polar surface. However, the main surface may be set to the nitrogen polar surface, and the back surface may be set to the Group-III element polar surface. An epitaxial crystal may be grown on the main surface, and various devices may be produced thereon. The back surface may be held with a susceptor or the like to transfer the Group-III element nitride semiconductor substrate according to the embodiment of the present invention.

In the description of the Group-III element nitride semiconductor substrate according to the embodiment of the present invention, the first surface is described as the main surface, and the second surface is described as the back surface. Accordingly, in this description, the term “main surface” may be replaced with “first surface,” the term “first surface” may be replaced with “main surface,” the term “back surface” may be replaced with “second surface,” and the term “second surface” may be replaced with “back surface.”

The main surface may be a mirror surface or a non-mirror surface. The main surface is preferably a mirror surface.

The main surface is preferably a surface from which an affected layer is substantially removed and which has a small surface roughness in a microscopic region from the viewpoint of obtaining such a semiconductor device that devices to be produced by epitaxially growing device layers have satisfactory characteristics and variations in device characteristics between the devices are reduced.

The back surface may be a mirror surface or a non-mirror surface.

The term “mirror surface” refers to a surface subjected to mirror processing, the surface being brought into a state in which the roughness and waviness of the surface are reduced to such an extent that light is reflected after the mirror processing, and hence the fact that an object is reflected on the surface subjected to the mirror processing can be visually observed. In other words, the term refers to a surface in a state in which the magnitude of each of the roughness and waviness of the surface after the mirror processing is reduced to such an extent as to be sufficiently negligible with respect to the wavelength of visible light. An epitaxial crystal can be sufficiently grown on the surface subjected to the mirror processing.

Any appropriate method may be adopted as a method for the mirror processing to the extent that the effect exhibited by the embodiment of the present invention is not impaired. An example of such method is a method including performing the mirror processing through use of one, or a combination of two or more, of the following apparatus: a polishing apparatus using a tape; a lapping apparatus using diamond abrasive grains; and a chemical mechanical polishing (CMP) apparatus using a slurry such as colloidal silica and a polishing pad made of a nonwoven fabric. When the affected layer remains on the surface after the processing, the affected layer is typically removed. As a method of removing the affected layer, there are given, for example, a method including removing the affected layer through use of reactive ion etching (RIE) or a chemical liquid, and a method including annealing the substrate.

The term “non-mirror surface” refers to a surface that is not subjected to mirror processing, and a typical example thereof is a rough surface obtained by surface-roughening treatment.

Any appropriate method may be adopted as a method for the surface-roughening treatment to the extent that the effect exhibited by the embodiment of the present invention is not impaired. Examples of such method include: grinding with an abrasive stone; laser texture processing; etching treatment with various chemical liquids and gases; physical or chemical coating treatment; and texturing by machining.

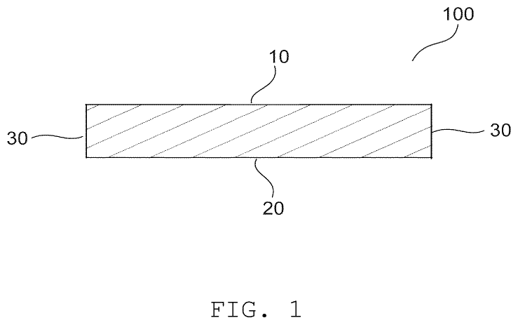

FIG. 1 is a typical schematic sectional view of the Group-III element nitride semiconductor substrate according to the embodiment of the present invention. As illustrated in FIG. 1, a Group-III element nitride semiconductor substrate 100 according to the embodiment of the present invention typically has a main surface (Group-III element polar surface) 10 and a back surface (nitrogen polar surface) 20. The Group-III element nitride semiconductor substrate 100 according to the embodiment of the present invention may have a side surface 30.

An end portion of the Group-III element nitride semiconductor substrate according to the embodiment of the present invention may adopt any appropriate form to the extent that the effect exhibited by the embodiment of the present invention is not impaired. Examples of the shape of the end portion of the Group-III element nitride semiconductor substrate according to the embodiment of the present invention include: a shape in which a main surface side and a back surface side are each chamfered so as to be a flat surface; a shape in which the main surface side and the back surface side are each chamfered in an R-shape; a shape in which only the main surface side of the end portion is chamfered so as to be a flat surface; and a shape in which only the back surface side of the end portion is chamfered so as to be a flat surface.

When the end portion of the Group-III element nitride semiconductor substrate according to the embodiment of the present invention is chamfered, the chamfered portion may be arranged over the one entire round of an outer peripheral portion, or may be arranged only in part of the outer peripheral portion. This outer peripheral portion is typically a region where no device is formed.

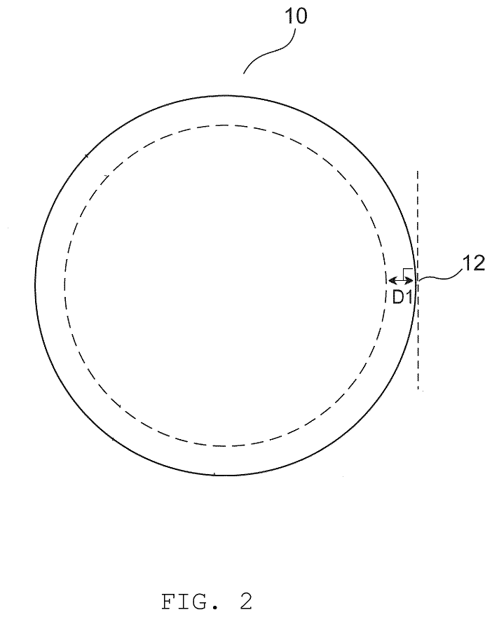

As illustrated in FIG. 2, such outer peripheral portion is a region from an outer peripheral end portion 12 to a portion distant therefrom by a width D1 toward the inside of a main surface 10 over the entire circumference of the substrate.

The width D1 of the chamfered portion of the main surface is a distance starting from the outer peripheral end portion 12, and is a distance in a normal direction toward the inside of the main surface 10 with respect to a tangent at the outer peripheral end portion 12. The width D1 is preferably constant.

Any appropriate size may be adopted as the width D1 to the extent that the effect exhibited by the embodiment of the present invention is not impaired. The width D1 is preferably 5 mm or less, more preferably 4 mm or less, still more preferably 3 mm or less, particularly preferably 2 mm or less, most preferably 1 mm or less because the effect exhibited by the embodiment of the present invention can be further expressed. The lower limit of the width D1 is preferably 0.3 mm or more because the effect exhibited by the embodiment of the present invention can be further expressed.

The minimum value of a specific resistance in the first surface of the Group-III element nitride semiconductor substrate according to the embodiment of the present invention is 1×10⁷ Ω·cm or more, preferably 1×10⁸ Ω·cm or more, more preferably 1×10⁹ Ω·cm or more, still more preferably 1×10¹⁰ Ω·cm or more, particularly preferably 1×10¹¹ Ω·cm or more. When the minimum value of the specific resistance in the first surface of the Group-III element nitride semiconductor substrate according to the embodiment of the present invention falls within the above-mentioned ranges, variations in characteristics between devices formed on the substrate can be suppressed.

The minimum value of the specific resistance in the first surface of the Group-III element nitride semiconductor substrate according to the embodiment of the present invention is 0.01 or more times, preferably from 0.01 times to 1.0 times, more preferably from 0.1 times to 1.0 times, still more preferably from 0.5 times to 1.0 times, particularly preferably from 0.8 times to 1.0 times as large as the maximum value of the specific resistance in the first surface. When the ratio of the minimum value of the specific resistance in the first surface of the Group-III element nitride semiconductor substrate according to the embodiment of the present invention to the maximum value thereof is adjusted within the above-mentioned ranges, the variations in characteristics between the devices formed on the substrate can be suppressed.

The inventors of the present invention have conceived that a variation in quality in the surface of a semi-insulating GaN freestanding substrate may be responsible for variations in characteristics of a conventional GaN-HEMT device, and have paid attention to the variation in quality in the surface of the semi-insulating GaN freestanding substrate. Then, the inventors have investigated a semi-insulating GaN substrate including devices having poor characteristics in detail. As a result, the inventors have revealed that the electrical resistivity distribution of the substrate has a problem, and have revealed that a region having a low resistance is partially present in the substrate. In view of the foregoing, the inventors have made a further investigation, and as a result, have found the following. When a semi-insulating GaN substrate including a first surface and a second surface is designed while the minimum value of a specific resistance in the first surface is adjusted within a predetermined range, and the ratio of the minimum value of the specific resistance to the maximum value thereof is adjusted within a predetermined range as described above, a semi-insulating GaN substrate in which the presence of a low-resistance region is suppressed can be obtained, and hence variations in characteristics between devices formed on the substrate can be suppressed.

Measurement intervals in the measurement of the above-mentioned specific resistance are each preferably 10 mm or less, more preferably 5 mm or less, still more preferably 4 mm or less, still more preferably 3 mm or less, particularly preferably 2 mm or less, more particularly preferably 1 mm or less. When the measurement intervals in the measurement of the above-mentioned specific resistance are set within the above-mentioned ranges, the variations in characteristics between the devices formed on the Group-III element nitride semiconductor substrate according to the embodiment of the present invention can be further suppressed. In other words, in the first surface of the Group-III element nitride semiconductor substrate according to the embodiment of the present invention, the minimum value of the specific resistance in preferably any appropriate region measuring 10 mm by 10 mm, more preferably any appropriate region measuring 5 mm by 5 mm, still more preferably any appropriate region measuring 4 mm by 4 mm, still more preferably any appropriate region measuring 3 mm by 3 mm, particularly preferably any appropriate region measuring 2 mm by 2 mm, more particularly preferably any appropriate region measuring 1 mm by 1 mm is typically 1×10⁷ Ω·cm or more, and the minimum value of the specific resistance in the appropriate region is typically 0.01 or more times as large as the maximum value of the specific resistance in the appropriate region. The minimum value of the specific resistance, and a ratio between the minimum value and maximum value of the specific resistance are each preferably as described above.

The above-mentioned specific resistance may be measured by any appropriate method to the extent that the effect exhibited by the embodiment of the present invention is not impaired. Examples of such method of measuring the specific resistance include an electric capacitance method, a two-terminal method, and a double ring electrode method.

Each of the two-terminal method and the double ring method is destructive measurement, and typically includes: cutting the substrate into a size suited for a measurement range to provide individual pieces; forming electrodes on the front surface and back surface of each piece; and then performing current-voltage measurement to measure the specific resistance thereof.

The electric capacitance method is nondestructive measurement, and typically includes: applying a high voltage from the front surface of the substrate with a probe in a non-contact manner under a state in which the back surface of the substrate is placed on a conductive stage; and measuring the specific resistance of the substrate from the transient response of charge obtained by electric capacitance measurement. At this time, the measurement may be performed at any appropriate position of the substrate by moving the probe or the stage in XY directions.

The measurement of the above-mentioned specific resistance is preferably performed through mapping measurement in the first surface by the electric capacitance method because of the following reason: the method is a non-contact specific resistance measurement method and enables a precise grasp of a specific resistance distribution in the surface of the substrate, and hence the effect exhibited by the embodiment of the present invention can be further expressed. The mapping measurement is typically performed by moving the probe in the XY directions.

Although an eddy current method is also given as an example of the non-contact specific resistance measurement method, the method is not suitable for the measurement of the specific resistance of a semi-insulating Group-III element nitride semiconductor substrate because a specific resistance to be measured by the method ranges from 10⁻³ Ω·cm to 10² Ω·cm .

The measurement of the above-mentioned specific resistance is preferably performed while the outer peripheral portion illustrated in FIG. 2 described above is omitted because the effect exhibited by the embodiment of the present invention can be further expressed.

An oxygen concentration in the Group-III element nitride semiconductor substrate according to the embodiment of the present invention measured by SIMS is preferably from 2×10¹⁶ atoms/cm³ to 6×10¹⁶ atoms/cm³, more preferably from 2×10¹⁶ atoms/cm³ to 5×10¹⁶ atoms/cm³, still more preferably from 2×10¹⁶ atoms/cm³ to 4×10¹⁶ atoms/cm³, particularly preferably from 2×10¹⁶ atoms/cm³ to 3×10¹⁶ atoms/cm³. The inventors of the present invention have found that when a Group-III element nitride semiconductor substrate is designed while an oxygen concentration in the Group-III element nitride semiconductor substrate measured by SIMS is adjusted within the above-mentioned predetermined ranges to suppress variations, a Group-III element nitride semiconductor substrate in which the presence of a low-resistance region is further suppressed can be obtained, and hence variations in characteristics between devices formed on the substrate can be further suppressed. Accordingly, when the oxygen concentration in the Group-III element nitride semiconductor substrate according to the embodiment of the present invention measured by the SIMS falls within the above-mentioned ranges, the variations in characteristics between the devices formed on the substrate can be further suppressed.

The Group-III element nitride semiconductor substrate according to the embodiment of the present invention is preferably free of a nanopipe therein. The inventors of the present invention have found that when a Group-III element nitride semiconductor substrate is designed so that the presence of a nanopipe in the Group-III element nitride semiconductor substrate may be suppressed, a Group-III element nitride semiconductor substrate in which the presence of a low-resistance region is further suppressed can be obtained, and hence variations in characteristics between devices formed on the substrate can be further suppressed. Accordingly, when the Group-III element nitride semiconductor substrate according to the embodiment of the present invention is free of a nanopipe therein, the variations in characteristics between the devices formed on the substrate can be further suppressed. When the Group-III element nitride semiconductor substrate includes a nanopipe therein, the effect exhibited by the embodiment of the present invention may be hardly expressed.

The Group-III element nitride semiconductor substrate according to the embodiment of the present invention may be produced by any appropriate method to the extent that the effect exhibited by the embodiment of the present invention is not impaired. A method of producing the Group-III element nitride semiconductor substrate according to the embodiment of the present invention, which is preferred because the effect exhibited by the embodiment of the present invention is further expressed, is described below.

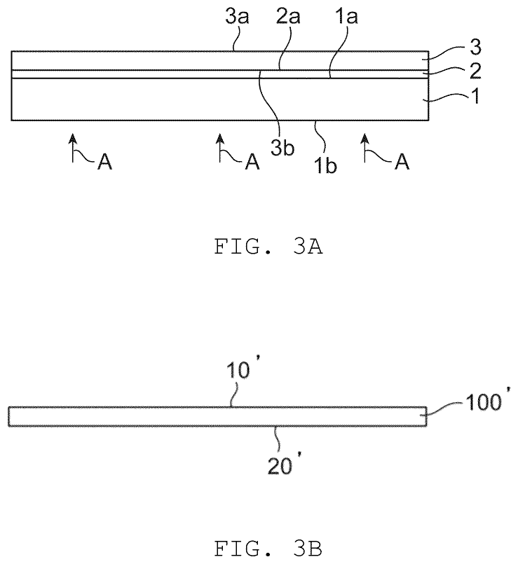

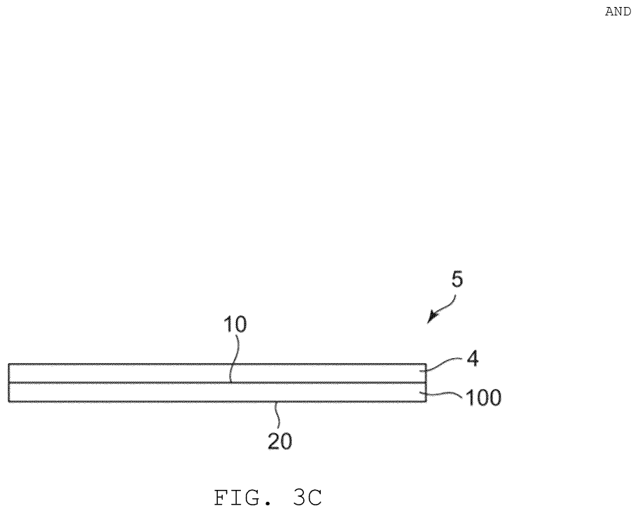

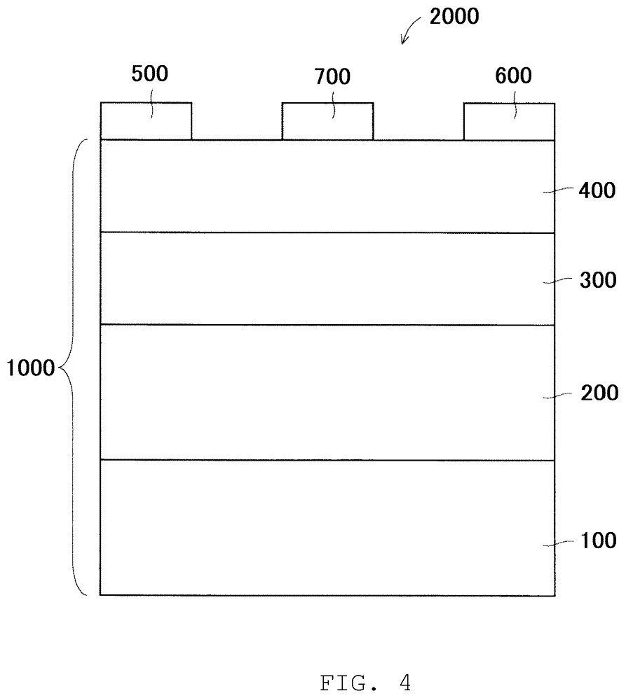

In the method of producing the Group-III element nitride semiconductor substrate according to the embodiment of the present invention, typically, as illustrated in FIG. 3A, a seed crystal film 2 is formed on a main surface 1a of a base substrate 1, and a Group-III element nitride layer 3 is formed on a Group-III element polar surface 2a of the seed crystal film 2. Next, a Group-III element nitride layer (seed crystal film 2+Group-III element nitride layer 3) serving as a freestanding substrate is separated from the base substrate 1. Thus, a freestanding substrate 100′ having a main surface 10′ and a back surface 20′ is obtained.

Any appropriate material may be adopted as a material for the base substrate to the extent that the effect exhibited by the embodiment of the present invention is not impaired.

Examples of such material include sapphire, crystal oriented alumina, gallium oxide, AlₓGa₁₋ₓN (0≤x≤1), GaAs, and SiC.

Any appropriate material may be adopted as a material for the seed crystal film to the extent that the effect exhibited by the embodiment of the present invention is not impaired. Examples of such material include AlₓGa₁₋ₓN (0≤x≤1) and InₓGa₁₋ₓN (0≤x≤1). Of those, gallium nitride is preferred. The material for the seed crystal film is more preferably gallium nitride that is recognized to show a yellow luminescence effect when observed with a fluorescence microscope. The term “yellow luminescence” refers to a peak (yellow luminescence (YL) or a yellow band (YB)) appearing in the range of from 2.2 eV to 2.5 eV in addition to an exciton transition (UV) from a band to another band.

Any appropriate formation method may be adopted as a method of forming the seed crystal film to the extent that the effect exhibited by the embodiment of the present invention is not impaired. Such formation method is, for example, a vapor growth method, and preferred examples thereof include a metal-organic chemical vapor deposition (MOCVD) method, a hydride vapor phase epitaxy (HVPE) method, a pulsed excitation deposition (PXD) method, a molecular beam epitaxy (MBE) method, and a sublimation method. Of those, a MOCVD method is more preferred as the method of forming the seed crystal film.

The formation of the seed crystal film by the MOCVD method is preferably performed by, for example, depositing a low-temperature grown buffer layer by from 20 nm to 50 nm at from 450° C. to 550° C., and then laminating a film having a thickness of from 2 μm to 4 μm at from 1, 000° C. to 1, 200° C.

Any appropriate growth direction may be adopted as the growth direction of the Group-III element nitride crystal layer to the extent that the effect exhibited by the embodiment of the present invention is not impaired. Examples of such growth direction include: the normal direction of the c-plane of a wurtzite structure; the normal direction of each of the a-plane and m-plane thereof; and the normal direction of a plane tilted from each of the c-plane, the a-plane, and the m-plane.

Any appropriate formation method may be adopted as a method of forming the Group-III element nitride crystal layer to the extent that the effect exhibited by the embodiment of the present invention is not impaired as long as a layer to be formed by the method has a crystal direction substantially following the crystal direction of the seed crystal film. Examples of such formation method include: gas phase growth methods, such as a MOCVD method, a HVPE method, a PXD method, a MBE method, and a sublimation method; liquid phase growth methods, such as a Na flux method, an ammonothermal method, a hydrothermal method, and a sol-gel method; a powder growth method utilizing solid phase growth of powder; and a combination thereof.

When the Na flux method is adopted as the method of forming the Group-III element nitride crystal layer, the Na flux method is preferably performed in conformity with a production method described in JP 5244628 B2 by appropriately adjusting the conditions and the like so that the effect exhibited by the embodiment of the present invention can be further expressed.

The formation of the Group-III element nitride crystal layer by the Na flux method is typically preferably performed as follows: a seed crystal substrate (base substrate+seed crystal film) is arranged in a crucible serving as a growing container under a nitrogen atmosphere; a melt composition containing a Group-III element, metal Na, and a dopant (e.g., Fe, Mn, or Zn) is further loaded into the crucible; the crucible is lidded; the lidded crucible is loaded into an external container; the external container is further loaded into a pressure-resistant container; and in a nitrogen atmosphere, after the temperature and pressure of the container are increased to preferably from 700° C. to 1,000° C. (more preferably from 800° C. to 900° C.) and preferably from 1 MPa to 7 MPa (more preferably from 2 MPa to 6 MPa), the container is rotated while the temperature and the pressure are retained.

At least one selected from Fe, Mn, and Zn is preferably adopted as the dopant, and Zn is more preferably adopted because the effect exhibited by the embodiment of the present invention can be further expressed.

Any appropriate crucible that may be used in the Na flux method may be adopted as the above-mentioned crucible to the extent that the effect exhibited by the embodiment of the present invention is not impaired. An alumina crucible coated with aluminum nitride (AlN) is preferably adopted as the above-mentioned crucible, and an alumina crucible, which has been coated with aluminum nitride (AlN) and then subjected to heat treatment, is more preferably adopted because the effect exhibited by the embodiment of the present invention can be further expressed. In particular, when the alumina crucible, which has been coated with aluminum nitride (AlN) and then subjected to the heat treatment, is adopted, the denseness of the AlN film can be improved by the heat treatment to reduce the mixing of impurities (contaminations) such as oxygen in a highly effective manner. Accordingly, for example, the growth starting point of a nanopipe hardly occurs, and hence the effect exhibited by the embodiment of the present invention can be further expressed.

The above-mentioned heat treatment may be performed by any appropriate method to the extent that the effect exhibited by the embodiment of the present invention is not impaired. The above-mentioned heat treatment is performed under, for example, a nitrogen atmosphere at a temperature in the range of preferably from 1,500° C. to 1,950° C., more preferably from 1,600° C. to 1,850° C. for a time period of preferably from 10 minutes to 90 minutes, more preferably from 20 minutes to 60 minutes because the effect exhibited by the embodiment of the present invention can be further expressed.

In addition, an aluminum nitride (AlN) crucible that has heretofore been adopted has a problem in that an increase in size of the crucible is difficult and the crucible is costly. Meanwhile, the alumina crucible coated with aluminum nitride (AlN) is suitable for the production of a large-diameter Group-III element nitride semiconductor substrate because an increase in size of the crucible is easy.

Any appropriate lid of a crucible that may be used in the Na flux method may be adopted as the lid of the crucible to the extent that the effect exhibited by the embodiment of the present invention is not impaired. An alumina lid coated with aluminum nitride (AlN) is preferably adopted as the lid of the crucible because the effect exhibited by the embodiment of the present invention can be further expressed. When the alumina crucible coated with aluminum nitride (AlN) is adopted, the mixing of impurities (contaminations) such as oxygen can be reduced in a highly effective manner. Accordingly, for example, the growth starting point of a nanopipe hardly occurs, and hence the effect exhibited by the embodiment of the present invention can be further expressed.

The rotation is typically performed as follows: the container is placed on a rotating table; and the container is rotated about a center axis with a constant period.

The rotation is performed so that the crystal growth rate of the Group-III element nitride crystal layer on the seed crystal substrate may be preferably from 5 μm/h to 25 μm/h, more preferably from 10 μm/h to 25 μm/h. When the crystal growth rate of the Group-III element nitride crystal layer on the seed crystal substrate is less than 5 μm/h, a crystal growth time is excessively prolonged, and actual production may be difficult. When the crystal growth rate is more than 25 μm/h, the content of an inclusion may be increased.

The rotation is preferably performed as follows: (i) rotation in one direction is performed without reverse rotation; (ii) a reverse operation including rotation in one direction for 1 minute or more and subsequent rotation in the opposite direction for 1 minute or more is repeated; or (iii) an intermittent operation including rotation in one direction for 5 seconds or more, followed by stopping for 0.1 second or more, and subsequent rotation in the same direction for 5 seconds or more is repeated. In the case of the above-mentioned item (ii) or (iii), when the reverse operation or the intermittent operation is repeated with a period shorter than the above-mentioned period, the crystal growth rate is excessively increased, and the content of an inclusion may be increased.

The rotation is preferably performed by clockwise motion and counterclockwise motion with a constant period because the effect exhibited by the embodiment of the present invention can be further expressed.

Next, the freestanding substrate including the Group-III element nitride crystal layer may be obtained by separating the Group-III element nitride crystal layer from the base substrate.

Any appropriate method may be adopted as a method of separating the Group-III element nitride crystal layer from the base substrate to the extent that the effect exhibited by the embodiment of the present invention is not impaired. Examples of such method include: a method including causing the Group-III element nitride crystal layer to spontaneously separate from the base substrate through use of a thermal shrinkage difference in a temperature decrease step after the growth of the Group-III element nitride crystal layer; a method including separating the Group-III element nitride crystal layer from the base substrate through chemical etching; as illustrated in FIG. 3A, a method including separating the Group-III element nitride crystal layer from the base substrate by a laser lift-off method including applying laser light from the back surface 1b side of the base substrate 1 as indicated by the arrows A; and a method including separating the Group-III element nitride crystal layer from the base substrate through grinding. In addition, the freestanding substrate including the Group-III element nitride crystal layer may be obtained by slicing the Group-III element nitride crystal layer through utilization of a wire saw or the like.

In the Group-III element nitride crystal layer thus obtained by the Na flux method, it is preferred that a plate surface thereof be flattened by being ground with an abrasive stone or the like, and the plate surface be then smoothened, for example, by being lapped with diamond abrasive grains.

Next, the freestanding substrate is shaped into a circular shape having a desired diameter by grinding its outer peripheral portion.

The size of the freestanding substrate is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches). The size (diameter) of the freestanding substrate is preferably 75 mm or more. When the freestanding substrate has a large size (diameter) as described above, the substrate is easily applied to a high-frequency and high-power electronic device, and in particular, is easily applied to a device handling large power, the device having a large device size along with the handling.

Specific examples of the large-diameter Group-III element nitride semiconductor substrate include a 4-inch wafer, a 6-inch wafer, an 8-inch wafer, and a 12-inch wafer.

Next, the main surface and/or the back surface is subjected to removal processing by, for example, grinding, lapping, or polishing so that the semiconductor substrate may be thinned and flattened to a desired thickness. Thus, a freestanding substrate is obtained.

The thickness of the freestanding substrate (when the thickness is not constant, the thickness of a place having the largest thickness) is preferably 100 μm or more, more preferably from 300 μm to 1,000 μm.

The outer peripheral edge of the freestanding substrate is chamfered through grinding as required. Thus, the Group-III element nitride semiconductor substrate 100 according to the embodiment of the present invention is finally obtained.

A crystal can be epitaxially grown on the main surface (Group-III element polar surface) 10 of the Group-III element nitride semiconductor substrate 100 to be obtained, and as illustrated in FIG. 3C, the formation of a functional layer 4 can provide a functional device 5. A back surface (nitrogen polar surface) is represented by reference numeral 20.

The epitaxial crystal to be grown on the Group-III element nitride semiconductor substrate to be obtained may be, for example, gallium nitride, aluminum nitride, indium nitride, or a mixed crystal thereof. Specific examples of such epitaxial crystal include GaN, AlN, InN, GaₓAl₁₋ₓN (1>x>0), GaₓIn₁₋ₓN (1>x>0), AlₓIn₁₋ₓN (1>x>0), and GaₓAl_{y}In_{z}N (1>x>0, 1>y>0, x+y+z=1). In addition, examples of the functional layer to be arranged on the Group-III element nitride semiconductor substrate to be obtained include a rectifying device, a switching device, and a power conversion device in addition to a light-emitting layer. In addition, the thickness and thickness distribution of the freestanding substrate may be reduced by subjecting the nitrogen polar surface to processing, such as grinding or polishing, after the arrangement of the functional layer on the Group-III element polar surface of the Group-III element nitride semiconductor substrate to be obtained.

### Epitaxial Substrate and HEMT Device

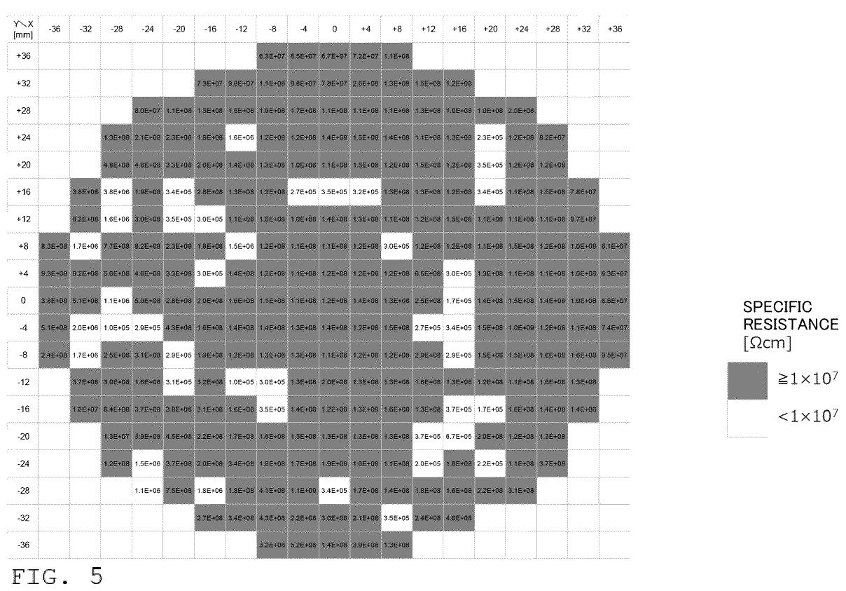

FIG. 4 is a schematic sectional view for illustrating a sectional structure of a HEMT device 2000 formed so as to include an epitaxial substrate 1000 according to the embodiment of the present invention.

The epitaxial substrate 1000 according to the embodiment of the present invention includes: the Group-III element nitride semiconductor substrate 100 according to the embodiment of the present invention; a buffer layer 200; a channel layer 300; and a barrier layer 400. In addition, the HEMT device 2000 is obtained by arranging a source electrode 500, a drain electrode 600, and a gate electrode 700 on the epitaxial substrate 1000 (on the barrier layer 400). A ratio between the thicknesses of the respective layers in FIG. 4 does not reflect an actual ratio.

The buffer layer 200 is a layer having a thickness of typically from 10 nm to 1,000 nm, the layer being (adjacently) formed on the first surface of the Group-III element nitride semiconductor substrate 100 according to the embodiment of the present invention. Unlike a so-called low-temperature buffer layer to be formed at a low temperature of typically less than 800° C., the buffer layer 200 is formed at a temperature comparable to the temperature at which the channel layer 300 or the barrier layer 400 is formed.

In the epitaxial substrate 1000, the buffer layer 200 is arranged as a diffusion-suppressing layer that suppresses the diffusion of a dopant (typically, Zn), which is doped into the Group-III element nitride semiconductor substrate 100 according to the embodiment of the present invention, toward the channel layer 300, and moreover, the barrier layer 400 above the layer at the time of the production of the epitaxial substrate 1000.

The buffer layer 200 is preferably formed of at least one kind selected from AlGaN and AlN.

The channel layer 300 is a layer (adjacently) formed on the buffer layer 200. The channel layer 300 is typically formed so as to have a thickness of from 50 nm to 5,000 nm.

The channel layer 300 is preferably formed of GaN.

The barrier layer 400 is a layer arranged on a side opposite to the buffer layer 200 across the channel layer 300. The barrier layer 400 is typically formed so as to have a thickness of from 2 nm to 40 nm.

As illustrated in FIG. 4, the barrier layer 400 may be formed so as to be adjacent to the channel layer 300. In this case, an interface between both the layers serves as a heterojunction interface. Alternatively, a spacer layer (not shown) may be arranged between the channel layer 300 and the barrier layer 400. In this case, a region from an interface between the channel layer 300 and the spacer layer to an interface between the barrier layer 400 and the spacer layer serves as a heterojunction interface region. AlN is preferably used in the spacer layer.

The barrier layer 400 is preferably formed of at least one kind selected from InAlGaN, InAlN, and AlGaN.

The formation of each of the buffer layer 200, the channel layer 300, and the barrier layer 400 is achieved by, for example, a MOCVD method. In, for example, the case where the buffer layer 200 is formed from AlGaN, the channel layer 300 is formed from GaN, and the barrier layer 400 is formed from AlGaN, the layer formation by the MOCVD method may be performed as follows: while the Group-III element nitride semiconductor substrate 100 according to the embodiment of the present invention mounted in a reactor is heated to a predetermined temperature with a known MOCVD furnace configured to be capable of supplying a metal-organic (MO) raw material gas (TMG or TMA) for Ga or Al, an ammonia gas, a hydrogen gas, and a nitrogen gas into the reactor, a GaN crystal or an AlGaN crystal produced by a vapor phase reaction between the metal-organic raw material gas corresponding to each layer and the ammonia gas is sequentially deposited on the Group-III element nitride semiconductor substrate 100 according to the embodiment of the present invention.

The source electrode 500 and the drain electrode 600 are each typically a metal electrode having a thickness of from ten and several nanometers to one hundred and several tens of nanometers. The source electrode 500 and the drain electrode 600 are each suitably formed as, for example, a multilayer electrode formed of Ti, Al, Ni, and Au. The source electrode 500 and the drain electrode 600 are each brought into ohmic contact with the barrier layer 400. In a suitable example, the source electrode 500 and the drain electrode 600 are each formed by a vacuum deposition method and a photolithography process. To improve the ohmic contact of each of both the electrodes, after the formation of the electrode, the electrode is preferably subjected to heat treatment in a nitrogen gas atmosphere at a predetermined temperature between 650° C. and 1,000° C. for several tens of seconds.

The gate electrode 700 is typically a metal electrode having a thickness of from ten and several nanometers to one hundred and several tens of nanometers. The gate electrode 700 is suitably formed as, for example, a multilayer electrode formed of Ni and Au. The gate electrode 700 is brought into Schottky contact with the barrier layer 400. In a suitable example, the gate electrode 700 is formed by a vacuum deposition method and a photolithography process.

### Production of Epitaxial Substrate

Production by a MOCVD method is described as one embodiment of a method of producing the epitaxial substrate 10 according to the embodiment of the present invention. The epitaxial substrate 1000 is obtained by laminating and forming the buffer layer 200, the channel layer 300, and the barrier layer 400 in the stated order under the below-indicated conditions and under a state in which the Group-III element nitride semiconductor substrate 100 according to the embodiment of the present invention is mounted on a susceptor arranged in the reactor of a MOCVD furnace. The term “formation temperature” means a susceptor heating temperature.

The term “Group-XV/Group-XIII gas ratio” as used herein refers to the ratio (molar ratio) of the supply amount of ammonia, which is a Group-XV (N) raw material, to the total supply amount of trimethylgallium (TMG), trimethylaluminum (TMA), and trimethylindium (TMI), which are Group-XIII (Ga, Al, and In) raw materials. In addition, the term “Al raw material gas/Group-XIII raw material gas ratio” when the barrier layer 400 is formed from AlGaN refers to the ratio (molar ratio) of the supply amount of an Al raw material to the supply amount of the entirety of the Group-XIII (Ga and Al) raw materials, and the term “In raw material gas/Group-XIII raw material gas ratio” when the barrier layer 400 is formed from InAIN refers to the ratio (molar ratio) of the supply amount of an In raw material to the supply amount of the entirety of the Group-XIII (In and Al) raw materials. In each case, the ratio is determined in accordance with the desired composition (Al molar ratio “x” or In composition ratio “y”) of the barrier layer 400.

Buffer Layer 200:
Formation temperature=from 900° C. to 1,200° C.
Pressure in reactor=from 5 kPa to 30 kPa
Carrier gas=hydrogen
Group-XV/Group-XIII gas ratio=from 5,000 to 20,000
Al raw material gas/Group-XIII raw material gas ratio=from 0.00002 to 1.0
Thickness=from 10 nm to 500 nm

Channel Layer 300:
Formation temperature=from 1,000° C. to 1,200° C.
Pressure in reactor=from 15 kPa to 105 kPa
Carrier gas=hydrogen
Group-XV/Group-XIII gas ratio=from 1,000 to 10,000
Thickness=from 50 nm to 5,000 nm

Barrier Layer 400 (in the case where the barrier layer is formed from AlGaN):
Formation temperature=from 1,000° C. to 1,200° C.
Pressure in reactor=from 1 kPa to 30 kPa
Group-XV/Group-XIII gas ratio=from 5,000 to 20,000
Carrier gas=hydrogen
Al raw material gas/Group-XIII raw material gas ratio=from 0.1 to 0.4
Thickness=from 2 nm to 40 nm

Barrier Layer 400 (in the case where the barrier layer is formed from InAlN):
Formation temperature=from 700° C. to 900° C.
Pressure in reactor=from 1 kPa to 30 kPa
Group-XV/Group-XIII gas ratio=from 2,000 to 20,000
Carrier gas=nitrogen
In raw material gas/Group-XIII raw material gas ratio=from 0.1 to 0.9
Thickness=from 2 nm to 40 nm

Barrier Layer 400 (in the case where the barrier layer is formed from InAlGaN):
Formation temperature=from 700° C. to 1,000° C.
Pressure in reactor=from 1 kPa to 30 kPa
Group-XV/Group-XIII gas ratio=from 2,000 to 20,000
Carrier gas=nitrogen
Al raw material gas/Group-XIII raw material gas ratio=from 0.1 to 0.9
In raw material gas/Group-XIII raw material gas ratio=from 0.1 to 0.9
Thickness=from 2 nm to 40 nm

### Production of HEMT Device

The production of the HEMT device 2000 may be achieved by using the epitaxial substrate 1000 according to the embodiment of the present invention through the application of a known technology.

For example, device separation treatment in which a site serving as a boundary between individual devices is removed by etching to a depth of from about 50 nm to about 1,000 nm through use of a photolithography process and a reactive ion etching (RIE) method is performed. After that, a SiO₂ film having a thickness of from 50 nm to 500 nm is formed on the surface of the epitaxial substrate 1000 (the surface of the barrier layer 400). Subsequently, the SiO₂ film at each of the sites at which the source electrode 500 and the drain electrode 600 are to be formed is removed by etching through use of photolithography. Thus, a SiO₂ pattern layer is obtained.

Next, a metal pattern formed of Ti, Al, Ni, and Au is formed at the sites at which the source electrode 500 and the drain electrode 600 are to be formed through use of a vacuum deposition method and the photolithography process to form the source electrode 500 and the drain electrode 600. The thicknesses of the respective metal layers of the pattern, that is, the Ti, Al, Ni, and Au layers are preferably set within the range of from 5 nm to 50 nm, the range of from 40 nm to 400 nm, the range of from 4 nm to 40 nm, and the range of from 20 nm to 200 nm in the stated order.

After that, to improve the ohmic properties of the source electrode 500 and the drain electrode 600, the electrodes are preferably subjected to heat treatment in a nitrogen gas atmosphere at from 600° C. to 1,000° C. for from 10 seconds to 1,000 seconds.

Subsequently, the SiO₂ film at the site at which the gate electrode 700 is to be formed is removed from the SiO₂ pattern layer through use of the photolithography process.

Further, a Schottky metal pattern formed of Ni and Au is formed at the site at which the gate electrode 700 is to be formed through use of the vacuum deposition method and the photolithography process to form the gate electrode 700. The thicknesses of the respective metal layers of the pattern, that is, the Ni and Au layers are preferably set within the range of from 4 nm to 40 nm and the range of from 20 nm to 200 nm, respectively.

Through the foregoing process, the HEMT device 2000 is obtained.

### EXAMPLES

The present invention is specifically described below by way of Examples. However, the present invention is by no means limited to these Examples. Test and evaluation methods in Examples and the like are as described below. The term “part(s)” in the below description means “part(s) by weight” unless otherwise specified, and the term “%” in the below description means “wt %” unless otherwise specified.

### Measurement of Specific Resistance in First Surface of Group-III Element Nitride Semiconductor Substrate

Measurement was performed by an electric capacitance method. COREMA-WT manufactured by SemiMap Scientific Instruments GmbH was used as a specific resistance-measuring apparatus. A probe having a probe diameter of 1 mm was used, and the mapping measurement of the specific resistance of the main surface (first surface) of a substrate was performed by moving the probe in the XY directions. The measurement was performed at intervals of 4 mm. In addition, the measurement was performed while a region in the outermost peripheral portion of the substrate (region from the outermost periphery thereof to a portion distant therefrom by 1.5 mm) where no device was formed was omitted.

### Measurement of Oxygen Concentration

The measurement of an oxygen concentration was performed from the main surface (first surface) of the substrate by using secondary ion mass spectrometry (SIMS).

### Observation of Presence or Absence of Nanopipe with Transmission Electron Microscope

The presence or absence of a nanopipe was observed with a transmission electron microscope. A sample piece to be used in the observation was sampled from the main surface (first surface) side of the substrate by using a focused ion beam method so that a section of the substrate was able to be observed. At the time of the observation, an electron beam was caused to enter so as to be parallel to a [10-10] direction, and the observation was performed in a bright field and a dark field based on a weak-beam method. In the observation in the dark field based on the weak-beam method, vectors [11-20] and were each used as a diffraction vector “g”. Of the observed defects, a defect, which was observed under the condition of each of the bright field and the dark field based on the weak-beam method, and had a width in a [11-20] direction of 20 nm or more, was judged as a nanopipe.

### Evaluation of Device Withstand Voltage of HEMT Device

A drain voltage Vdb defined as follows was adopted as an indicator for evaluating the device withstand voltage of the resultant HEMT device: when a drain voltage Vd was gradually increased from 0 V while a gate voltage Vg of −10 V was applied, the voltage at which a drain current Id exceeded 1×10⁻⁵ A (1×10⁻⁴ A/mm when normalized by a gate width of 100 μm) for the first time was defined as the drain voltage Vdb. The Vdb is desirably as large as possible. When Vdb≥300 V, it was judged that the HEMT device had a sufficient device withstand voltage, and the evaluation was performed by the following criteria.

All the devices each have a Vdb of 300 V or more.: ∘

At least one of the devices have a Vdb of less than 300 V.: x

### Comparative Example 1

A seed crystal film made of gallium nitride having a thickness of 2 μm was formed on a sapphire substrate having a diameter of 3 inches by a MOCVD method to provide a seed crystal substrate.

The resultant seed crystal substrate was arranged in an alumina crucible coated with AlN in a glove box under a nitrogen atmosphere.

Next, metal gallium and metal sodium serving as raw materials and granular manganese serving as a doping material were loaded into the crucible, and the crucible was lidded with an alumina lid coated with AlN. Metal gallium and metal sodium were loaded so that the following ratio was obtained: Ga/(Ga+Na) (mol %) =15 mol %.

The lidded crucible was loaded into an internal container made of stainless steel, and was further loaded into an external container made of stainless steel capable of housing the internal container. The external container was closed with a container lid equipped with a nitrogen introduction pipe. The external container was arranged on a rotating table placed on a heating portion in a crystal production apparatus having been vacuum-baked in advance, and a pressure-resistant container storing the external container was lidded and sealed.

Next, the inside of the pressure-resistant container was evacuated to 0.1 Pa or less with a vacuum pump. Subsequently, while an upper-stage heater, a middle-stage heater, and a lower-stage heater were adjusted to perform heating so that a heated space had a temperature of 870° C., a nitrogen gas was introduced from a nitrogen gas cylinder up to 4.0 MPa, and the external container was rotated about a center axis at a speed of 20 rpm in clockwise motion and counterclockwise motion with a constant period. Then, the container was retained under that state for 40 hours. After that, the container was naturally cooled to room temperature and reduced in pressure to atmospheric pressure. After that, the lid of the pressure-resistant container was opened, and the crucible was taken out of the container. Solidified metal sodium in the crucible was removed, and a gallium nitride crystal grown on the seed crystal substrate was collected.

UV laser light was applied from the sapphire substrate side to decompose the gallium nitride crystal on the seed crystal substrate, and the grown gallium nitride crystal was separated from the sapphire substrate. The outer peripheral portion of the gallium nitride crystal after the separation was ground with a diamond abrasive stone so that the diameter thereof was adjusted to 75 mm.

Next, the gallium nitride crystal was bonded to a ceramic-made processing surface plate, and its Ga polar surface was ground and polished with a grinder and a lapping apparatus. As final finish, the surface was subjected to mirror finish with diamond abrasive grains each having a particle diameter of 0.1 μm.

The gallium nitride crystal was turned inside out, and was fixed to the ceramic-made processing surface plate, followed by similar grinding and polishing of its nitrogen polar surface. As final finish, the surface was subjected to mirror finish with diamond abrasive grains each having a particle diameter of 0.1 μm.

A wafer (C1) serving as a gallium nitride freestanding substrate was produced by the foregoing production method.

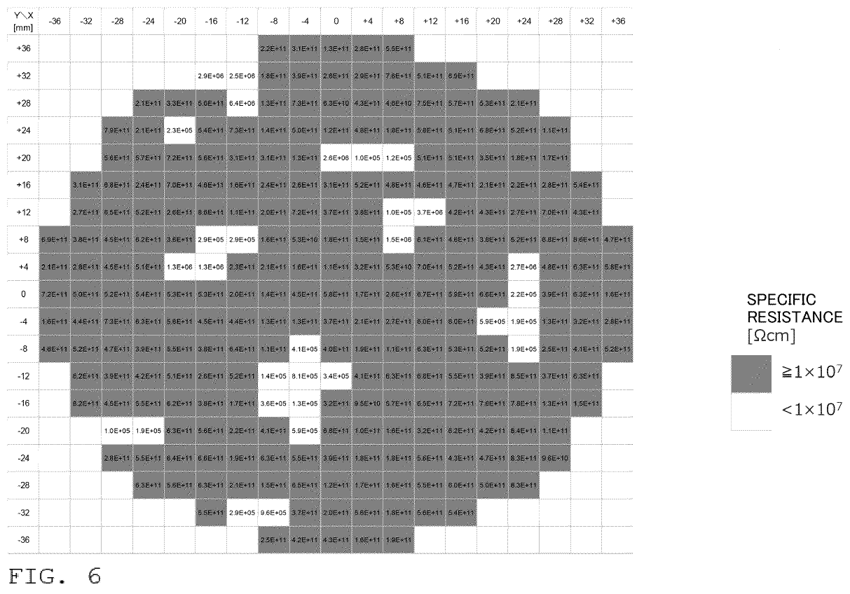

The specific resistance of the wafer (C1) at room temperature was measured by an electric capacitance system. The specific resistance was measured as follows: mapping measurement was performed in the main surface of the wafer at intervals of 4 mm and at 277 points. The specific resistance showed a large variation in the main surface, and its minimum value was 1.0×10⁵ Ω·cm (measurement lower limit) and its maximum value was 1.1×10⁹ Ω·cm. Accordingly, the ratio of the minimum value to the maximum value was 9.1×10⁻⁵. The results of the mapping measurement of the specific resistance are shown in FIG. 5.

A region at X=−28 mm and Y=0 mm, and a region at X=+16 mm and Y=0 mm, which had shown low resistances in the measurement of the specific resistance of the wafer (C1), were subjected to secondary ion mass spectrometry (SIMS). As a result, oxygen concentrations in the former region and the latter region were 1×10¹⁷ atoms/cm³ and 2×10¹⁷ atoms/cm³, respectively. In addition, a region at X=0 mm and Y=0 mm, which had shown a high resistance, was subjected to SIMS measurement. As a result, an oxygen concentration in the region was 4×10¹⁶ atoms/cm³.

When the region at X=+16 mm and Y=0 mm, which had shown a low resistance in the measurement of the specific resistance of the wafer (C1), was observed with a transmission electron microscope, as shown in FIG. 11, a nanopipe was observed in the crystal. Meanwhile, when the region at X=0 mm and Y=0 mm, which had shown a high resistance in the measurement of the specific resistance of the wafer (C1), was observed with the transmission electron microscope, no nanopipe was observed in the crystal.

### Comparative Example 2

A wafer (C2) serving as a gallium nitride freestanding substrate was produced under the same conditions as those of Comparative Example 1 by using granular zinc as a doping material.

The specific resistance of the wafer (C2) at room temperature was measured by an electric capacitance system. The specific resistance was measured as follows: mapping measurement was performed in the main surface of the wafer at intervals of 4 mm and at 277 points. The specific resistance showed a large variation in the main surface, and its minimum value was 1.0×10⁵ Ω·cm (measurement lower limit) and its maximum value was 8.6×10¹¹ Ω·cm. Accordingly, the ratio of the minimum value to the maximum value was 1.2×10⁻⁷. The results of the mapping measurement of the specific resistance are shown in FIG. 6.

A region at X=+24 mm and Y=−4 mm and a region at X=0 mm and Y=+20 mm, which had shown low resistances in the measurement of the specific resistance of the wafer (C2), were subjected to secondary ion mass spectrometry (SIMS). As a result, oxygen concentrations in the former region and the latter region were 2×10¹⁷ atoms/cm³ and 8×10¹⁶ atoms/cm³, respectively. In addition, a region at X=0 mm and Y=+12 mm, which had shown a high resistance, was subjected to SIMS measurement. As a result, an oxygen concentration in the region was 5×10¹⁶ atoms/cm³.

When the region at X=+24 mm and Y=−4 mm, which had shown a low resistance in the measurement of the specific resistance of the wafer (C2), was observed with a transmission electron microscope, a nanopipe was observed in the crystal. Meanwhile, when the region at X=0 mm and Y=+12 mm, which had shown a high resistance in the measurement of the specific resistance of the wafer (C2), was observed with the transmission electron microscope, no nanopipe was observed in the crystal.

### Comparative Example 3

A wafer (C3) serving as a gallium nitride freestanding substrate was produced under the same conditions as those of Comparative Example 1 by using granular iron as a doping material.

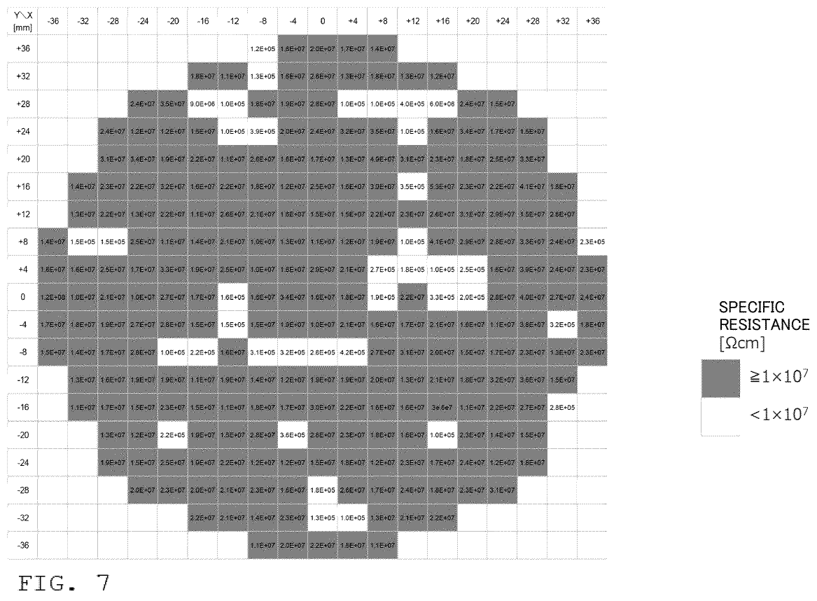

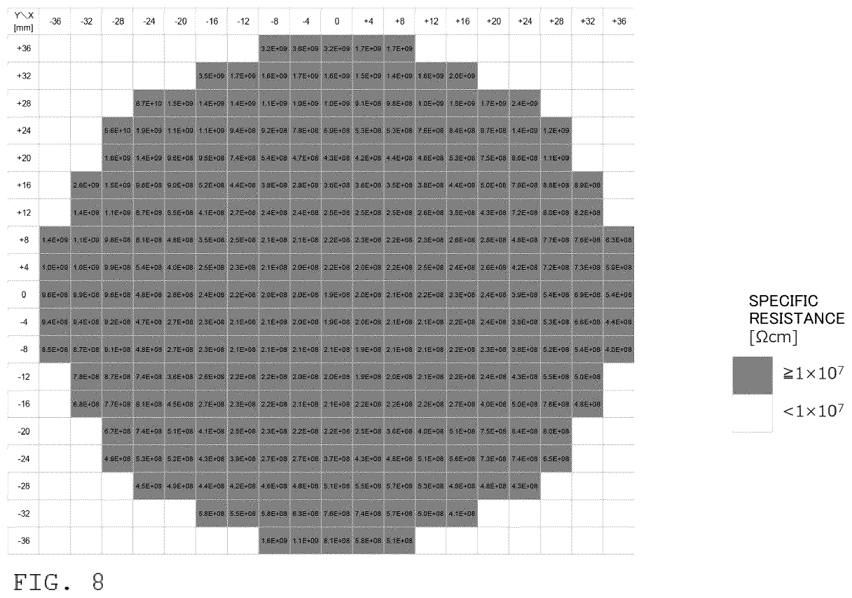

The specific resistance of the wafer (C3) at room temperature was measured by an electric capacitance system. The specific resistance was measured as follows: mapping measurement was performed in the main surface of the wafer at intervals of 4 mm and at 277 points. The specific resistance showed a large variation in the main surface, and its minimum value was 1.0×10⁵ Ω·cm (measurement lower limit) and its maximum value was 1.2×10⁸ Ω·cm. Accordingly, the ratio of the minimum value to the maximum value was 8.3×10⁻⁴. The results of the mapping measurement of the specific resistance are shown in FIG. 7.

A region at X=0 mm and Y=+8 mm and a region at X=+4 mm and Y=+16 mm, which had shown low resistances in the measurement of the specific resistance of the wafer (C3), were subjected to secondary ion mass spectrometry (SIMS). As a result, oxygen concentrations in the former region and the latter region were 2×10¹⁷ atoms/cm³ and 4×10¹⁷ atoms/cm³, respectively. In addition, a region at X=0 mm and Y=+4 mm, which had shown a high resistance, was subjected to SIMS measurement. As a result, an oxygen concentration in the region was 6×10¹⁶ atoms/cm³.

When the region at X=0 mm and Y=+8 mm, which had shown a low resistance in the measurement of the specific resistance of the wafer (C3), was observed with a transmission electron microscope, a nanopipe was observed in the crystal. Meanwhile, when the region at X=0 mm and Y=+4 mm, which had shown a high resistance in the measurement of the specific resistance of the wafer (C3), was observed with the transmission electron microscope, no nanopipe was observed in the crystal.

### Example 1

A seed crystal film made of gallium nitride having a thickness of 2 μm was formed on a sapphire substrate having a diameter of 3 inches by a MOCVD method to provide a seed crystal substrate.

The resultant seed crystal substrate was arranged in an alumina crucible, which had been coated with AlN and then subjected to heat treatment and washing with hydrofluoric acid, in a glove box under a nitrogen atmosphere. The heat treatment was performed by retaining the crucible at 1,700° C. for 30 minutes under a nitrogen atmosphere.

Next, metal gallium and metal sodium serving as raw materials and granular manganese serving as a doping material were loaded into the crucible, and the crucible was lidded with an alumina lid coated with AlN. Metal gallium and metal sodium were loaded so that the following ratio was obtained: Ga/(Ga+Na) (mol %)=15 mol %.

The lidded crucible was loaded into an internal container made of stainless steel, and was further loaded into an external container made of stainless steel capable of housing the internal container. The external container was closed with a container lid equipped with a nitrogen introduction pipe. The external container was arranged on a rotating table placed on a heating portion in a crystal production apparatus having been vacuum-baked in advance, and a pressure-resistant container storing the external container was lidded and sealed.

Next, the inside of the pressure-resistant container was evacuated to 0.1 Pa or less with a vacuum pump. Subsequently, while an upper-stage heater, a middle-stage heater, and a lower-stage heater were adjusted to perform heating so that a heated space had a temperature of 870° C., a nitrogen gas was introduced from a nitrogen gas cylinder up to 4.0 MPa, and the external container was rotated about a center axis at a speed of 20 rpm in clockwise motion and counterclockwise motion with a constant period. Then, the container was retained under that state for 40 hours. After that, the container was naturally cooled to room temperature and reduced in pressure to atmospheric pressure. After that, the lid of the pressure-resistant container was opened, and the crucible was taken out of the container. Solidified metal sodium in the crucible was removed, and a gallium nitride crystal grown on the seed crystal substrate was collected.

UV laser light was applied from the sapphire substrate side to decompose the gallium nitride crystal on the seed crystal substrate. Thus, the grown gallium nitride crystal was separated from the sapphire substrate. The outer peripheral portion of the gallium nitride crystal after the separation was ground with a diamond abrasive stone so that the diameter thereof was adjusted to 75 mm.

Next, the gallium nitride crystal was bonded to a ceramic-made processing surface plate, and its Ga polar surface was ground and polished with a grinder and a lapping apparatus. As final finish, the surface was subjected to mirror finish with diamond abrasive grains each having a particle diameter of 0.1 μm.

The gallium nitride crystal was turned inside out, and was fixed to the ceramic-made processing surface plate, followed by similar grinding and polishing of its nitrogen polar surface. As final finish, the surface was subjected to mirror finish with diamond abrasive grains each having a particle diameter of 0.1 μm.

A wafer (1) serving as a gallium nitride freestanding substrate was produced by the foregoing production method.

The specific resistance of the wafer (1) at room temperature was measured by an electric capacitance system. The specific resistance was measured as follows: mapping measurement was performed in the main surface of the wafer at intervals of 4 mm and at 277 points. A specific resistance of 1×10⁷ Ω·cm or more was obtained over the entire surface of the wafer. The minimum value and maximum value of the specific resistance were 1.9×10⁸ Ω·cm and 8.7×10¹⁰ Ω·cm , respectively, and hence the ratio of the minimum value to the maximum value was 0.022. The results of the mapping measurement of the specific resistance are shown in FIG. 8.

A region at X=0 mm and Y=0 mm, a region at X=+20 mm and Y=0 mm, and a region at X=+36 mm and Y=0 mm in the wafer (1) were subjected to SIMS measurement. As a result, oxygen concentrations in the first, second, and third regions were 5×10¹⁶ atoms/cm³, 3×10¹⁶ atoms/cm³, and 2×10¹⁶ atoms/cm³, respectively.

When the region at X=0 mm and Y=0 mm, the region at X=+20 mm and Y=0 mm, and the region at X=+36 mm and Y=0 mm in the wafer (1) were each observed with a transmission electron microscope, no nanopipe was observed in the crystal.

### Example 2

A wafer (2) serving as a gallium nitride freestanding substrate was produced under the same conditions as those of Example 1 by using granular zinc as a doping material.

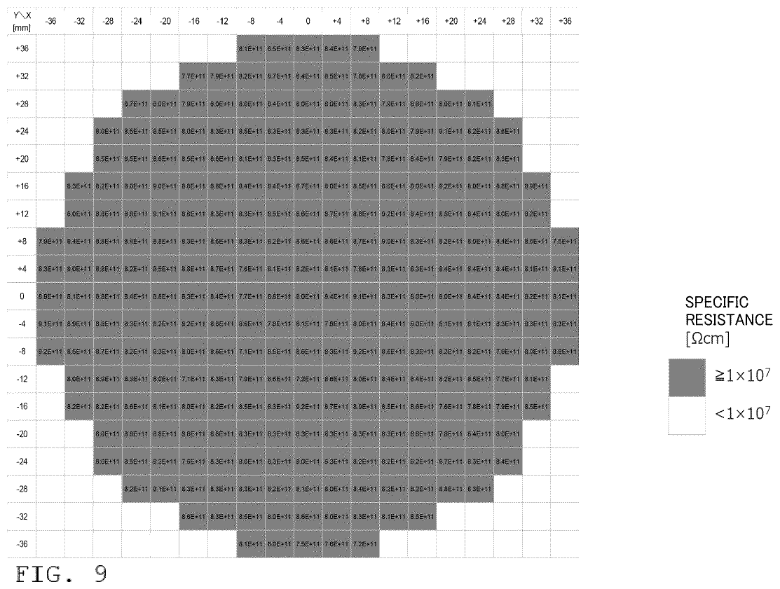

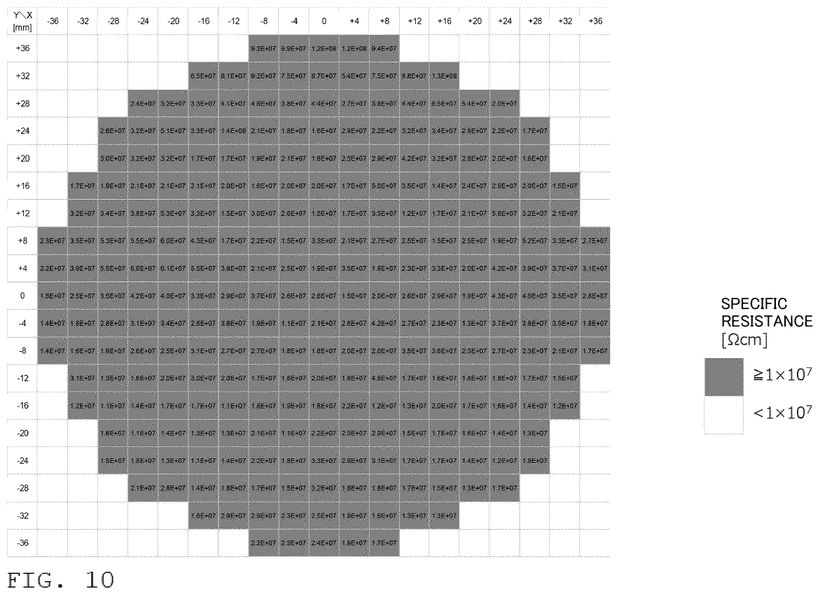

The specific resistance of the wafer (2) at room temperature was measured by an electric capacitance system. The specific resistance was measured as follows: mapping measurement was performed in the main surface of the wafer at intervals of 4 mm and at 277 points. A specific resistance of 1×10⁷ Ω·cm or more was obtained over the entire surface of the wafer. The minimum value and maximum value of the specific resistance were 7.1×10¹¹ Ω·cm and 9.2×10¹¹ Ω·cm , respectively, and hence the ratio of the minimum value to the maximum value was 0.77. The results of the mapping measurement of the specific resistance are shown in FIG. 9.

A region at X=0 mm and Y=0 mm, a region at X=0 mm and Y=+20 mm, and a region at X=0 mm and Y=+36 mm in the wafer (2) were subjected to SIMS measurement. As a result, oxygen concentrations in the first, second, and third regions were 4×10¹⁶ atoms/cm³, 2×10¹⁶ atoms/cm³, and 3×10¹⁶ atoms/cm³, respectively.

When the region at X=0 mm and Y=0 mm, the region at X=0 mm and Y=+20 mm, and the region at X=0 mm and Y=+36 mm in the wafer (2) were each observed with a transmission electron microscope, no nanopipe was observed in the crystal.

### Example 3

A wafer (3) serving as a gallium nitride freestanding substrate was produced under the same conditions as those of Example 1 by using granular iron as a doping material.

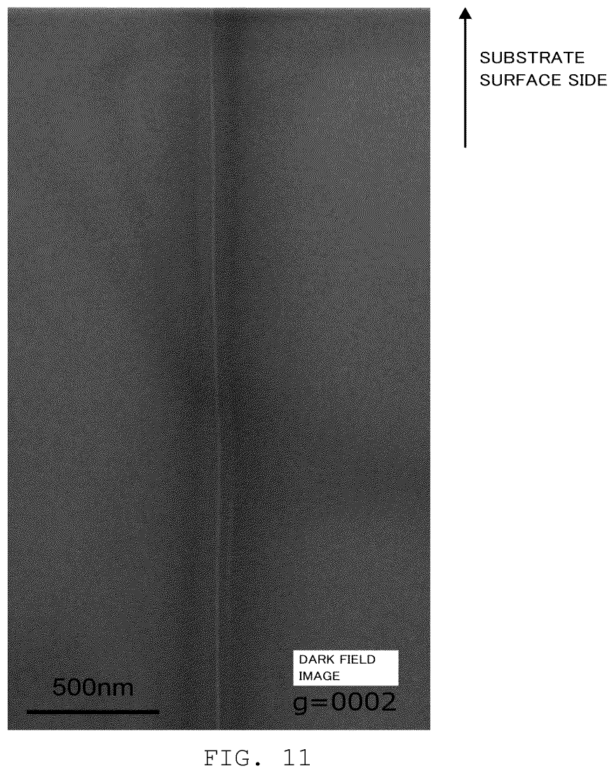

The specific resistance of the wafer (3) at room temperature was measured by an electric capacitance system. The specific resistance was measured as follows: mapping measurement was performed in the main surface of the wafer at intervals of 4 mm and at 277 points. A specific resistance of 1×10⁷ Ω·cm or more was obtained over the entire surface of the wafer. The minimum value and maximum value of the specific resistance were 1.1×10⁷ Ω·cm and 1.4×10⁸ Ω·cm , respectively, and hence the ratio of the minimum value to the maximum value was 0.079. The results of the mapping measurement of the specific resistance are shown in FIG. 10.

A region at X=0 mm and Y=0 mm, a region at X=0 mm and Y=+20 mm, and a region at X=0 mm and Y=+36 mm in the wafer (3) were subjected to SIMS measurement. As a result, oxygen concentrations in the first, second, and third regions were 3×10¹⁶ atoms/cm³, 6×10¹⁶ atoms/cm³, and 5×10¹⁶ atoms/cm³, respectively.

When the region at X=0 mm and Y=0 mm, the region at X=0 mm and Y=+20 mm, and the region at X=0 mm and Y=+36 mm in the wafer (3) were each observed with a transmission electron microscope, no nanopipe was observed in the crystal.

### Comparative Examples 4 to 6 and Examples 4 to 6 (Production of Epitaxial Substrate)

A buffer layer, a channel layer, and a barrier layer were laminated and formed in the stated order on each of the wafers (C1) to (C3) and (1) to (3), which were gallium nitride freestanding substrates produced in Comparative Examples 1 to 3 and Examples 1 to 3, by a MOCVD method to produce an epitaxial substrate.

Specifically, the respective layers were laminated and formed under the below-indicated conditions and under a state in which each of the wafers (C1) to (C3) and (1) to (3), which were gallium nitride freestanding substrates produced in Comparative Examples 1 to 3 and Examples 1 to 3, was mounted on a susceptor arranged in the reactor of a MOCVD furnace. The term “formation temperature” means a susceptor heating temperature. The term “Group-XV/Group-XIII gas ratio” refers to the ratio (molar ratio) of the supply amount of ammonia, which is a Group-XV (N) raw material, to the total supply amount of trimethylgallium (TMG), trimethylaluminum (TMA), and trimethylindium (TMI), which are Group-XIII (Ga, Al, and In) raw materials. In addition, the term “Al raw material gas/Group-XIII raw material gas ratio” when AlGaN is formed refers to the ratio (molar ratio) of the supply amount of an Al raw material to the supply amount of the entirety of the Group-XIII (Ga and Al) raw materials, and the ratio is determined in accordance with the desired composition of AlGaN.

Buffer Layer: AlGaN
Formation temperature=1, 050° C.
Pressure in reactor=5 kPa
Group-XV/Group-XIII gas ratio=15,000
Al raw material gas/Group-XIII raw material gas ratio=0.001
Thickness=20 nm

Channel Layer: GaN
Formation temperature=1, 050° C.
Pressure in reactor=100 kPa
Group-XV/Group-XIII gas ratio=2,000
Thickness=1,000 nm

Barrier Layer: AlGaN
Formation temperature=1,050° C.
Pressure in reactor=5 kPa
Group-XV/Group-XIII gas ratio=12,000
Al raw material gas/Group-XIII raw material gas ratio=0.25
Thickness=25 nm

### (Production of HEMT Device)

A site serving as a boundary between the respective devices on the main surface of each of the epitaxial substrates was removed by etching to a depth of about 100 nm through use of a photolithography process and a RIE method. An interval between the boundaries was set to 1 mm.

Next, an electrode pattern formed of Ti, Al, Ni, and Au (whose thicknesses were 25 nm, 75 nm, 15 nm, and 100 nm, respectively) was formed at each of the sites at which a source electrode and a drain electrode were to be formed through use of the photolithography process and a vacuum deposition method. After that, the electrodes were subjected to heat treatment in nitrogen at 800° C. for 30 seconds.

Subsequently, a gate electrode pattern was formed at the site on the upper surface of each of the epitaxial substrates at which a gate electrode was to be formed through use of the photolithography process and the vacuum deposition method. A pattern formed of Ni and Au (whose thicknesses were 6 nm and 12 nm, respectively) was formed as the gate electrode. The gate electrode was formed so that the gate electrode had a gate length of 1 μm and a gate width of 100 μm, an interval between the gate electrode and the source electrode became 1 μm, and an interval between the gate electrode and the drain electrode became 10 μm.

Through the foregoing process, a HEMT device was obtained. The device withstand voltage of the resultant HEMT device was evaluated.

Some of the HEMT devices formed on each of the wafers (C1) to (C3), which were gallium nitride freestanding substrates produced in Comparative Examples 1 to 3, each had a Vdb of less than 300 V, and hence the result of their evaluation was “x (unsatisfactory).”

Meanwhile, all the HEMT devices formed on each of the wafers (1) to (3), which were gallium nitride freestanding substrates produced in Examples 1 to 3, each had a Vdb of 300 V or more, and hence the result of their evaluation was “∘ (satisfactory).”

The Group-III element nitride semiconductor substrate according to the embodiment of the present invention may be utilized as each of the substrates of various semiconductor devices.

What is claimed is:

1. A Group-III element nitride semiconductor substrate, comprising:
a first surface; and
a second surface,
wherein a minimum value of a specific resistance in the first surface is 1×10⁷ Ω·cm or more,
wherein the minimum value of the specific resistance in the first surface is 0.01 or more times as large as a maximum value of the specific resistance in the first surface, and
wherein measurement of the specific resistance is continuously performed at measurement intervals of 10 mm or less.

2. The Group-III element nitride semiconductor substrate according to claim 1, wherein the measurement of the specific resistance is performed through mapping measurement in the first surface by an electric capacitance method.

3. The Group-III element nitride semiconductor substrate according to claim 1, wherein the Group-III element nitride semiconductor substrate comprises Zn as a dopant.

4. The Group-III element nitride semiconductor substrate according to claim 1, wherein an oxygen concentration in the Group-III element nitride semiconductor substrate measured by SIMS is from 2×10¹⁶ atoms/cm³ to 6×10¹⁶ atoms/cm³.

5. The Group-III element nitride semiconductor substrate according to claim 1, wherein the Group-III element nitride semiconductor substrate is free of a nanopipe therein.

6. The Group-III element nitride semiconductor substrate according to claim 1, wherein the Group-III element nitride semiconductor substrate has a diameter of 75 mm or more.

7. An epitaxial substrate, comprising:
the Group-III element nitride semiconductor substrate of claim 1;
a buffer layer formed of at least one kind selected from AlGaN and AlN;
a channel layer formed of GaN; and
a barrier layer formed of at least one kind selected from InAlGaN, InAlN, and AlGaN,
the buffer layer, the channel layer, and the barrier layer being arranged in the stated order on the first surface of the Group-III element nitride semiconductor substrate.

8. A functional device, comprising:
the Group-III element nitride semiconductor substrate of claim 1;
a buffer layer formed of at least one kind selected from AlGaN and AlN;
a channel layer formed of GaN; and
a barrier layer formed of at least one kind selected from InAlGaN, InAlN, and AlGaN,
the buffer layer, the channel layer, and the barrier layer being arranged in the stated order on the first surface of the Group-III element nitride semiconductor substrate.

9. A Group-III element nitride semiconductor substrate, comprising:
a first surface; and
a second surface,
wherein a minimum value of a specific resistance in the first surface is 1×10⁷ Ω·cm or more,
wherein the minimum value of the specific resistance in the first surface is 0.01 or more times as large as a maximum value of the specific resistance in the first surface,
wherein measurement of the specific resistance is continuously performed at measurement intervals of 5 mm or less,
wherein the Group-III element nitride semiconductor substrate comprises Zn, Mn or Fe as a dopant,
wherein the Group-III element nitride semiconductor substrate is free of a nanopipe therein, and
wherein an oxygen concentration in the Group-III element nitride semiconductor substrate measured by SIMS is from 2×10¹⁶ atoms/cm³ to 6×10¹⁶ atoms/cm³.

10. The Group-III element nitride semiconductor substrate according to claim 9,
wherein the Group-III element nitride semiconductor substrate comprises Zn as a dopant,
wherein the minimum value of the specific resistance in the first surface is 1×10¹¹ Ω·cm or more, and
wherein the minimum value of the specific resistance in the first surface is 0.5 or more times as large as the maximum value of the specific resistance in the first surface.
